(19) United States
(12) Patent Application Publication
(10) Pub. No.: US 2019/0037649 A1
(43) Pub. Date: Jan. 31, 2019

(54) METHOD FOR REPAIRING SUBSTRATES WITH AN ELECTRICALLY CONDUCTIVE COATING AND LASER CUTTING PATTERN

(71) Applicant: SAINT-GOBAIN GLASS FRANCE, Courbevoie (FR)

(72) Inventors: Valentin SCHULZ, NIEDERZIER (DE); Stephan GILLESSEN, ALSDORF (DE)

(73) Assignee: Saint-Gobain Glass France, Courbevoie (FR)

(21) Appl. No.: 15/741,265

(22) PCT Filed: Nov. 3, 2016
(86) PCT No.: PCT/EP2016/076498

§ 371 Date: Mar. 30, 2018

(30) Foreign Application Priority Data
Dec. 17, 2015 (EP) 15200674.8

(51) Int. Cl. H05B 3/86; H05K 3/22

(52) U.S. Cl. CPC H05B 3/86; H05K 3/225; H05B 2203/005; H05B 2203/013; H05K 2203/162; H05B 2203/017; H05B 2203/011

(57) ABSTRACT

A method for processing a substrate is presented. The substrate includes an electrically conductive coating, and at least one isolating line that runs between first and second subregions of the electrically conductive coating. According to one aspect, the isolating line includes at least one defect with a proportion of less than 10% of the total surface area of the isolating line. First and second electric contacts are respectively connected to the first and second subregion. A voltage Uₙ is applied between the first and second electric contacts, and a measurement is taken to detect whether an electric current is flowing between the first and the second subregions. If a current is flowing, application of the voltage and measurement of the current are repeated with a voltage greater than or equal to Uₙ, until a current can no longer be measured.

The invention relates to a method for repairing substrates having an electrically conductive coating and a laser cutting pattern, a substrate having an electrically conductive coating and laser cutting pattern, and use thereof.

Transparent substrates having an electrically conductive coating are already used in a variety of applicational areas, for example, as a windshield in motor vehicles, as heatable mirrors, or also as heaters in living areas. In motor vehicles, these can be used in the form of heatable windshields, side windows, or rear windows to keep the vehicle windows free of ice and condensation. The heating elements present in a substrate should be hardly or not at all visible to the observer both for aesthetic reasons and for safety. The field of vision of windshields must, by law, have any limitations to visibility. Heating elements in windshields in the form of wires do, in fact, meet these legal requirements, but, especially in darkness and with backlighting, the wires cause bothersome reflections. In recent years, especially in the automotive sector, but also in the construction sector, panes with an infrared-reflecting electric coating are increasingly used. Such coatings have, on the one hand, good electrical conductivity, which enables heating of the pane, and, moreover, infrared-reflecting properties, which reduce undesirable heating of the interior by solar radiation. These layer systems are thus of particular significance, not only in terms of safety relevant aspects such as unrestricted visibility, but also for ecological reasons such as a reduction in harmful emissions and an improvement of vehicle comfort. The coatings include electrically conductive layers, in particular based on silver. The coatings are usually contacted electrically with two busbars, between which a current flows through the heatable coating. This type of heating is, for example, described in WO 03/024155 A2, US 2007/0082219 A1, and US 2007/0020465 A1, which disclose layer systems made of a plurality of silver layers, which further reduce the sheet resistance of the conductive coating.

Methods such as magnetically enhanced cathodic sputtering for the deposition of such layer systems are well known to the person skilled in the art. The transparent infrared-reflecting electrically conductive coating can be deposited either on one of the inward sides of the outer pane or of the inner pane or even on a carrier film that is inserted between the panes. Direct deposition of the coating on one of the pane surfaces is economically advantageous especially with production of large quantities and is thus the commonly used method for producing windshields.

Depending on the geometry of the substrate to be heated, the electrically conductive coating can be divided by isolating lines into various regions in order, for example, to obtain the most uniform heating possible or to produce individually controllable heating fields. Moreover, an edge region of the coating parallel to the substrate edge is electrically isolated to prevent corrosion of the coating by moisture and environmental influences.

EP 1626940 B1 discloses a heatable pane with a plurality of heating regions, in which an electrically conductive coating is applied, wherein the electrically conductive coating of one heating region is electrically isolated by isolating lines from the other heating regions. Mounted on the coating are busbars that enable heating of the coating by application of an electrical voltage. The individual heating regions function as serially connected resistance elements which heat up by means of the drop in voltage.

It is also known from WO 2014/060203 to increase the transmittance of high-frequency electromagnetic radiation selectively in an electrically conductive coating by means of coated regions and thus to enable the operation of mobile phones and satellite-supported navigation in the vehicle interior. According to the embodiments disclosed in WO 2014/060203, a plurality of concentrically arranged de-coated regions (isolating lines) are present, within which regions with an electrically conductive coating are situated.

For producing such substrates having de-coated regions, after deposition of the electrically conductive coating on a substrate, de-coated regions can be produced, for example, using a laser or by etching. In these known prior art methods for producing isolating lines, residues of the conductive coating or individual particles can remain in the region of the isolating lines such that the isolating lines are not continuous. Thus, the individual regions of the electrically conductive coating, which are supposed to be separated from one another by the introduction of an isolating line, are still electrically conductingly connected. This result, for example, in inhomogeneous heating of the substrate through local overheating of individual regions (formation of so-called “hot spots”). These substrates do not meet the required specifications.

The object of the present invention is to provide a simplified method for repairing laser cutting patterns on substrates having an electrically conductive coating, use thereof, as well as a corresponding substrate.

The object of the present invention is accomplished according to the invention by a method for processing a substrate having an electrically conductive coating according to claim 1, use thereof according to claim 14, as well as a corresponding substrate according to claim 9. Preferred embodiments emerge from the subclaims.

The method according to the invention for processing a substrate having an electrically conductive coating and at least one isolating line, comprises the following steps
a) Providing a substrate,
b) Contacting a first electric contact to a first subregion and contacting a second electric contact to a second subregion of the electrically conductive coating,
c) Applying a voltage Uₙ between the first electric contact and the second electric contact,
d) Measuring whether an electric current is flowing between the first subregion and the second subregion of the electrically conductive coating, by means of the first electric contact on the first subregion and by means of the second electric contact on the second subregion,
   e) Repeating the steps c) and d) with a voltage greater than or equal to Uₙ, if, in step d), a current was measured between the first subregion and the second subregion, until, in step d), a current is no longer flowing between the first subregion and the second subregion, and the electrically conductive coating and/or electrically conductive particles are thermally decomposed in the region of the defect.
   This can be, for example, an oxidation reaction.

A substrate having an electrically conductive coating can be, in the context the invention, a coating that is suitable for heating the substrate. Also, the invention further includes substrates having electrically conductive coatings on which no means for applying a voltage, for example, busbars, are mounted. Accordingly, infrared-reflecting coatings with the sole function of preventing heating of a space located behind the pane are also included. Infrared-reflecting coatings that are also electrically conductive but on which means for applying an electrical voltage are not necessarily present are known to the person skilled in the art.

The substrate in step a) has at least one electrically conductive coating on at least one surface of the substrate, wherein at least one isolating line is introduced into the electrically conductive coating, which line delimits at least one first subregion and one second subregion of the coating relative to one another. The isolating line optionally has at least one defect, at the position of which the local sheet resistance is lower than the sheet resistance of the isolating line outside the defect. The isolating line has the purpose of electrically isolating the first subregion of the coating from the second subregion of the coating. In the region of the isolating line, the electrically conductive coating is removed, with the isolating line having at least one defect, in the region of which the electrically conductive coating is removed only insufficiently or an electrically conductive particle has remained. In the region of the defect, the sheet resistance is thus substantially lower than in the region of the isolating line, by means of which electric current is conducted in the region of the defect and the two subregions of the electrically conductive coating are electrically contacted to one another. If a defect is present, the areal proportion of the defect to the total surface area of the isolating line is less than 10%.

In accordance with the method according to the invention, all substrates are post-treated in the production process and any isolating line defects present are repaired. In this regard, it is to be considered particularly advantageous that defective substrates do not have to be first identified and sorted, but, rather, all substrates go through this process. A voltage Uₙ is applied on all heatable substrates between the first subregion and the second subregion of the coating. If no defect of the isolating line is present, the first subregion and the second subregion are electrically isolated from one another and no current flows between these regions. In this case, the voltage applied causes no structural changes at all in the substrate. If a defect is present in the region of the isolating line, the first subregion and the second subregion are electrically contacted to one another via this defect and a current flows between these subregions via the defect. The defect is a really small compared to the isolating line (less than 10% of the total area of the isolating line) such that the current density in the region of the defect is large. Thus, very strong heating takes place in the region of the defect, which ultimately results in burning of the conductive coating or the conductive particles in the region of the defect. This region with thermally decomposed coating extends from one free end of the isolating line, through the region of the defect to the other free end of the isolating line. In this context, the term “free ends” refers to the sections of the isolating line immediately adjacent the defect. The region with thermally decomposed coating present in the region of the former defect is electrically insulating and electrically separates the first subregion of the coating from the second subregion of the coating. Thus, the defect is remedied and the substrate with a repaired defect exhibits heating behavior identical to substrates without any defect.

Thus, the rejects arising in the production process and the production costs associated therewith are significantly reduced.

In the next step of the method (step d), a measurement is taken, by means of the electric contacts that are applied on the first or second subregion of the coating, as to whether a current is flowing between these regions. If no current is flowing, the defect has been successfully repaired or no defect was present. In both cases, the process is terminated and the substrate is supplied to the further production process.

In step e) of the method according to the invention, the steps c) and d) are repeated one or more times with a voltage that corresponds at least to the voltage Uₙ from the preceding step c), if a current between the two subregions of the coating was measured in the preceding step d) and thus a defect of the isolating line is still present. By repeating step c) of the method, the overall time in which the defect is exposed to the voltage applied is lengthened. Thereafter, a check is again performed by means of step d) as to whether the repair was successful, and the steps c) and d) are repeated if necessary.

In the region of the isolating line, the resistance is, for example, comparable in magnitude to the resistance of the substrate material. The traces of the electrically conductive coating possibly remaining in the region of the intact isolating line are negligible. The resistance in the region of the isolating line is particularly preferably greater than 10⁶Ω.

In the region of the defect, the resistance is substantially lower than in the region of the isolating line. In the practical implementation of the method, a slight deviation is immaterial. The person skilled in the art will determine whether a defect is present by means of the measurement in step d) of the method according to the invention. When a defect as such is identifiable, the electrical resistance in the region of the defect is not substantially higher than the sheet resistance of the electrically conductive coating, as a result of which the electric current flows via the defect. The resistance in the region of the defect is particularly preferably less than 10⁶Ω. In practice, in the region of the defect, very low resistances usually appear, which are on the order of several ohms, 6Ω is mentioned here by way of example.

If, in step d) of the method, a current flow is still detected between the two subregions, the steps c) and d) can also be repeated with a voltage Uₙ₊₁, where Uₙ₊₁>Uₙ. Thereafter, a check is again performed by means of step d) as to whether the repair was successful, and the steps c) and d) are, optionally, repeated again with a further increased voltage. This iterative process is especially useful in the case of a first-time use of the method. The voltage necessary depends on the geometry of the substrate, the positioning of the electric contacts, and the nature of the electrically conductive coating, but can be determined empirically in a simple manner through the iterative procedure described. As soon there is such an empirical value for the voltage necessary with specific substrates, it is used with the subsequent substrates of the same nature already with the first execution of step c) of the method according to the invention. Thus, usually, only a one-time execution of the steps c) and d) is required, as soon as an operating range for the voltage has been determined.

As already discussed, the areal proportion of the defect to the total surface area of the isolating line should be less than 10%. Preferably, this proportion is less than 5%, particularly preferably less than 3%. The defect size is preferably less than 1000 μm, particularly preferably less than 700 μm, in particular less than 500 μm. Typical defect sizes are, for example, approx. 100 μm. These data are based on the respective size of one defect; however, a plurality of defects can be present within this magnitude. In practice, even panes with 5 or 7 intentionally produced defects of a magnitude within the ranges mentioned were successfully repaired by means of the method according to the invention.

Particularly in the case of a plurality of defects, it is possible that the steps c) and d) will have to be repeated multiple times in order to effect a complete repair of the isolating line. The voltage applied need not necessarily be increased; it is usually already sufficient to repeat step c) with the same voltage. It can, for example, happen that with the first execution of step c) only one defect was repaired. After that, the power density with an applied voltage increases in the region of the second defect. If, however, step c) has already been terminated by this time, the second defect is not repaired. In this case, it suffices to repeat step c) with the voltage previously used.

Particularly in the case of substrates with new designs, on which the method according to the invention has not yet been used, the person skilled in the art will start first with a relatively low voltage and increase this as needed. In an exemplary embodiment of the method on a windshield with two heating fields, in the first execution of step c), a voltage Uₙ of 5 V is applied and this is increased iteratively as necessary. The precise values of the voltage applied are immaterial in the execution of the method. A value of 5 V can already suffice in the case of small substrates with a short distance between the electric contacts applied and a coating with high conductivity. Thus, it is useful to select a value of this magnitude as a starting value. In practice, it has been demonstrated that depending on substrate size, coating, and positioning of the electric contacts, values between 10 V and 30 V are suitable in most cases.

In general, the voltages Uₙ or Uₙ₊₁ are preferably selected such that they are less than 200 V, particularly preferably less than 100 V, in particular between 3 V and 50 V. In the case of very small substrates with a coating having high conductivity and a short distance between the first electric contact and the second electric contact, 0.1 V can already suffice. In the method according to the invention, the suitable voltage range can be determined iteratively as needed.

In a particularly preferred embodiment of the method, the voltage applied to a substrate heated in the installed position is less than or equal to the voltage used in the regular operation of the substrate. If the substrate is used as a component of a heated windshield in vehicles with 14 V on-board voltage, the maximum voltage applied would, accordingly, be 14 V. It can thus be ensured that no damage to the coating or other components occurs through application of an unsuitably high voltage. However, it has been demonstrated in practice that even higher voltages are possible without causing damage. Even with a substrate whose coating is designed for an on-board voltage of 14 V, it has been demonstrated in practice that voltages of as much as 30 V and beyond are unproblematic. In the case of substrates that are to be operated in motor vehicles with an on-board voltage of 42 V or 48 V, the voltage can, accordingly, be selected higher. The limitation to the respective operating voltage is merely a precautionary measure.

The voltage to be applied in step c) of the method according to the invention also depends, in addition to the parameters mentioned, on the time period during which the voltage is applied. The shorter the time period, the higher the applied voltage selected tends to be. On the one hand, the time period should not be too long, in order to enable expeditious advancement of the process; on the other, for safety-related reasons, it is preferable not to operate at excessively high voltages. Usually, the voltage Uₙ or Uₙ₊₁ is applied for 1 second to 10 seconds, preferably 2 seconds to 6 seconds.

By way of example, the following combinations of time periods and voltages applied for executing process step c) are mentioned: 14 V for 5 seconds, 20 V for 5 seconds, or 20 V for 3 seconds. These parameters were tested using windshields as substrates; however, it has been demonstrated that these are also largely applicable to other substrate sizes. Particularly in the case of smaller substrate sizes, a lower voltage or shorter shorter time period would also suffice; however, it is advantageous not to have to alter the process.

The first electric contact and the second electric contact are means familiar to the person skilled in the art for making electric contact and are characterized by their good conductivity. The contacts can, for example, have a metallic coating, preferably a noble metal coating, for example, a gold coating, in order to enable the most loss-free voltage transmission possible. The contact can, for example, be implemented needle-shaped. If the production plant already has measurement electrodes for resistance measurement and quality control of the electrically conductive coating, these can be used as the first electric contact and as the second electric contact in method according to the invention. An additional financial investment as well as major modifications of the production process are thus not required for the use of the method according to the invention.

Preferably, the first electric contact is placed directly on the electrically conductive coating in the first subregion and the second electric contact is placed directly on the electrically conductive coating in the second subregion. Accordingly, in this step of the method, it is unnecessary to install busbars and/or connection elements, but, instead, the contacting can be done independent thereof. Depending on the arrangement of the first subregion, of the second subregion of the coating, and of the busbars, it can also be useful to place the first electric contact and the second electric contact directly on the electrically conductive coating, even though busbars were already mounted. This is, in particular, the case when at least one of the two subregions, between which the isolating line runs, is not provided to heat the pane. In this case, even in the subsequent course of the method, no busbars are provided in this unheated subregion and the corresponding electric contact must be placed directly on the electrically conductive coating. An example of this is a peripheral edge region of the coating, which is frequently separated from the rest of the coating by means of an isolating line, in order to avoid corrosion from moisture entering on the edge. This peripheral isolating line could also be repaired using the method according to the invention, wherein the peripheral edge region is a subregion not provided for heating the pane. Further examples in which a subregion of the electrically conductive coating that is not used for heating the substrate is partitioned off are known to the person skilled in the art.

The method according to the invention can thus also be used to process isolating lines between two subregions of the electrically conductive coating that are not heated in the subsequent product. The known prior art infrared-reflecting coatings previously mentioned that are also electrically conductive and heatable but not necessarily used for heating are one example of this.

Furthermore, substrate configurations can arise in which the busbars can be applied only after step e) of the method according to the invention. This is, for example, the case when a busbar establishes an electrically conductive connection between the subregions of the coating that are involved in the use of the method according to the invention. After applying a voltage via the first electric contact and the second electric contact, the flow of current would run via the corresponding busbar and not, as desired, via the defect of the isolating line. In this case, the method according to the invention should be executed first and the corresponding busbar should be applied only after step e).

If the busbars establish no electric contact between the first subregion and the second subregion of the coating, the busbar(s) can also be electrically conductingly contacted on the electrically conductive coating prior to step b) in the first subregion and/or the second subregion. In this case, the first electric contact and the second electric contact can be contacted to the busbars in step b). Alternatively, here, as well, direct electric contacting of the coating in the first subregion and in the second subregion is possible.

The busbars are provided to be connected to an external voltage source such that a current flows through the conductive coating between the busbars. The coating thus functions as a heating layer and heats the composite pane as a result of its electrical resistance, for example, to device or to defog the pane.

The mounting of the busbars can be done, in particular, by placing, printing, soldering, or gluing.

In a preferred embodiment, the busbars are implemented as a printed and fired conductive structure. The printed busbars contain at least one metal, preferably silver. The electrical conductivity is preferably realized via silver particles. The metal particles can be situated in an organic and/or inorganic matrix, such as pastes or inks, preferably as fired screenprinting paste with glass frits. The layer thickness of the printed busbars is preferably from 5 μm to 40 μm, particularly preferably from 8 μm to 20 μm, and most particularly preferably from 10 μm to 15 μm. Printed busbars with these thicknesses are technically easy to realize and have advantageous current carrying capacity.

Alternatively, the busbars are implemented as strips of an electrically conductive foil. The busbars then contain, for example, at least aluminum, copper, tinned copper, gold, silver, zinc, tungsten, and/or tin or alloys thereof. The strip preferably has a thickness from 10 μm to 500 μm, particularly preferably from 30 μm to 300 μm. Busbars made of electrically conductive foils with these thicknesses are technically easy to realize and have advantageous current carrying capacity. The strip can be electrically conductively connected to the electrically conductive coating, for example, via a soldering compound, via an electrically conductive adhesive, or an electrically conductive adhesive tape, or by direct placement. To improve the conducting connection, a silver-containing paste can be arranged between a conductive coating and a busbar, for example.

The electrically conductive coating is applied on the substrate prior to step a). Suitable methods for this are sufficiently known to the person skilled in the art. Usually, methods of physical vapor deposition (PVD) are used. Particularly preferably, the method of cathodic sputtering, in particular magnetically-enhanced cathodic sputtering (magnetron sputtering), is used. Thus, electrically conductive coatings can be produced in high electrical and optical quality quickly, economically, and, if need be, even with large areas.

The isolating line is produced by removing the electrically conductive coating in the region of the isolating line. For this, a variety of methods, for example, etching, mechanical abrasive methods, or laser methods, are known to the person skilled in the art. Laser methods are the most common methods according to the prior art. Laser machining is done with a wavelength from 300 nm to 1300 nm. The wavelength used depends on the type of coating. Pulsed solid-state lasers are preferably used as the laser source. The particles ablated during laser machining are removed by a particle exhauster. It has proved useful to focus the laser beam through the substrate onto the electrically conductive coating and to position the particle exhauster on the opposite side of the substrate. Thus, the particle exhauster is arranged in the immediate vicinity of the particles created during the laser process such that the exhausting is as effective as possible.

The isolating line preferably has a width of 1 μm to 10 mm, particularly preferably 10 μm to 2 mm, most particularly preferably 50 μm to 500 μm, in particular 50 μm to 200 μm, for example, 100 μm or 90 μm or 80 μm. Even these widths of the isolating line are sufficient to effect electrical isolation of the subregions of the electrically conductive coating from one another.

In a preferred embodiment of the method, after step e), the substrate is laminated, with the interposition of a thermoplastic intermediate layer, to a second substrate to form a composite pane.

The production of the laminated glass by lamination is done with customary methods known per se to the person skilled in the art, for example, autoclave methods, vacuum bag methods, vacuum ring methods, calender methods, vacuum laminators, or combinations thereof. The bonding of the outer pane and the inner pane is customarily done under the action of heat, vacuum, and/or pressure.

Suitable thermoplastic intermediate layers are sufficiently known to the person skilled in the art. Usually, the thermoplastic intermediate layer includes at least one laminating film made of polyvinyl butyral (PVB), ethylene vinyl acetate (EVA), or polyurethane (PU), preferably polyvinyl butyral (PVB). The thickness of the laminating films is preferably from 0.2 mm to 2 mm, particularly preferably from 0.3 mm to 1 mm, for example, 0.38 mm or 0.76 mm. The thermoplastic intermediate layer can also be made of a plurality of laminating films and, optionally, an additional film positioned between two laminating films. This additional film is used to introduce further functionalities. Thus, for example, thermoplastic intermediate layers made of a plurality of polymeric films that have acoustically damping properties are known.

The laminated glass can also be provided with an additional function, in that the thermoplastic intermediate layer has functional inlays, for example, inlays with IR-absorbing, UV-absorbing, and/or coloring properties. The inlays are, for example, organic or inorganic ions, compounds, aggregates, molecules, crystals, pigments, or dyes.

In an alternative embodiment of the method according to the invention, prior to step a), the substrate is laminated with a second substrate and a thermoplastic intermediate layer to form a laminated glass. Only after that are the steps a) to e) of the method according to the invention carried out. Such a procedure is also included within the scope of the invention. However, it was noted in experiments that clouding visible to the observer occurs in the laminated glass in the vicinity of the repaired defect of the isolating line. This is usually discernible as a grayish-black coloration. Since such negative effects are undesirable, a lamination process usually occurs after step e) of the method according to the invention.

The invention further includes a substrate obtainable according to the method of the invention, wherein the substrate includes at least one isolating line with at least one repaired defect. In a corresponding optical enlargement of the isolating line in the region of the repaired defect, this is unambiguously to be recognized as such and evidence that production using the method according to the invention occurred. In the region of the repaired defect, the electrically conductive coating has a region with thermally decomposed coating that extends between the two ends of the isolating line adjacent the defect. In the region of the repaired defect, the isolating line is completed by this region of thermally decomposed coating such that, in sum, there is a complete electrical separation of the subregions by means of the isolating line and said region.

In a preferred embodiment, the substrate is laminated to a second substrate with the interposition of a thermoplastic intermediate layer to form a composite pane.

The substrate and/or the second substrate preferably contain glass, particularly preferably flat glass, float glass, quartz glass, borosilicate glass, soda lime glass, or plastics, in particular polyethylene, polyethylene terephthalate, polypropylene, polycarbonate, polymethylmethacrylate, polystyrene, polyamide, polyester, polyvinyl chloride, and/or mixtures or copolymers thereof.

The thickness of the substrates can vary widely and thus be ideally adapted to the requirements in the individual case. Preferably, the thicknesses of the substrate and of the second substrate are from 0.5 mm to 10 mm and preferably from 1 mm to 5 mm, most particularly preferably from 1.4 mm to 3 mm.

The substrate, the second substrate, and/or the thermoplastic intermediate layer can be clear and colorless, but also tinted, frosted, or colored. The substrate and/or the second substrate can be made of non-prestressed, partially prestressed, or prestressed glass.

In an alternative embodiment of the invention, the substrate is a carrier film, on which the electrically conductive coating is applied and into which the isolating line is introduced. The method according to the invention, is not altered by this and also is to be used in this case as described. Subsequent to the method according to the invention, the carrier film with an electrically conductive coating can be used in a variety of glazings, for example, as an intermediate ply in a thermoplastic intermediate layer of a composite glass pane or even as a surface electrode in switchable glazings, for example, in the field of architectural glazing or automobile glazing.

According to the alternative embodiment of the substrate as a carrier film, the carrier film preferably includes contains at least polyethylene terephthalate (PET), polyethylene (PE), or mixtures or copolymers or derivatives thereof. That is particularly advantageous for handling, stability, and the optical properties of the carrier film. The carrier film preferably has a thickness of 5 μm to 500 μm, particularly preferably of 10 μm to 200 μm, and most particularly preferably of 12 μm to 75 μm. Carrier layers with these thicknesses can be advantageously provided in the form of flexible and, at the same time, stable films which can be easily handled.

In this alternative embodiment, the substrate (the carrier film) is likewise laminated to a second substrate with the interposition of a thermoplastic intermediate layer. In this case, a thermoplastic intermediate layer and an additional (third) substrate are also applied on the opposite side of the substrate. The third substrate corresponds in its composition to the possible compositions of the second substrate; however, the two can also have, in one composite pane, different compositions. A possible layer sequence of the alternative embodiment is: second substrate-thermoplastic intermediate layer-substrate (carrier film) with an electrically conductive coating and repaired isolating line-thermoplastic intermediate layer-third substrate.

The electrically conductive coating preferably contains, regardless of the embodiment of the substrate, silver and/or an electrically conductive oxide, particularly preferably silver, titanium dioxide, aluminum nitride, and/or zinc oxide, with silver being most particularly preferably used.

The electrically conductive coating is preferably transparent. In the context of the invention, this means a coating that has light transmittance greater than 70% in the spectral range from 500 nm to 700 nm. This is thus a coating intended and suitable for application on substantially the full area of the pane, with through-vision retained.

Some of the electrically conductive coatings known in the automotive sector have, at the same time, infrared-reflecting properties, which reduces heating of the space behind the pane. The electrically conductive coating is, in a preferred embodiment, infrared-reflecting. The electrically conductive coating has at least one electrically conductive layer. The coating can, additionally, have dielectric layers that serve, for example, for regulation of the sheet resistance, for corrosion protection, or for reducing reflection. The conductive layer preferably contains silver or an electrically conductive oxide (transparent conductive oxide, TCO) such as indium tin oxide (ITO). The conductive layer preferably has a thickness of 10 nm to 200 nm. To improve conductivity with, at the same time, high transparency, the coating can have a plurality of electrically conductive layers that are separated from one another by at least one dielectric layer. The conductive coating can, for example, contain two, three, or four electrically conductive layers. Typical dielectric layers contain oxides or nitrides, for example, silicon nitride, silicon oxide, aluminum nitride, aluminum oxide, zinc oxide, or titanium oxide. Such electrically conductive coatings are not restricted to use in heatable embodiments of the composite pane. Even in panes without a heating function, said infrared-reflecting electrically conductive coatings are used, with the coating fulfilling, in this case, only the purpose of solar protection.

In a particularly preferred embodiment, the electrically conductive coating has at least one electrically conductive layer, which contains silver, preferably at least 99% silver. The layer thickness of the electrically conductive layer is preferably from 5 nm to 50 nm, particularly preferably from 10 nm to 30 nm. The coating preferably has two or three of these conductive layers, which are separated from one another by at least one dielectric layer. Such coatings are particularly advantageous, for one thing, in terms of the transparency of the pane and, for another, in terms of their conductivity.

The sheet resistance of the electrically conductive coating is preferably from 0.5 ohms/square to 7.5 ohms/square. Thus, advantageous heat outputs are obtained with voltages customarily used in the vehicle sector, with low sheet resistances resulting in higher heat outputs with the same applied voltage.

Examples of layer structures that have both high electrical conductivity and an infrared-reflecting effect are known to the person skilled in the art from WO 2013/104439 and WO 2013/104438.

Preferably, the substrate is laminated with a second substrate and a thermoplastic intermediate layer to form a windshield, wherein the isolating line runs along the center of the pane perpendicular to the roof edge of the windshield. The “roof edge” of the windshield is the edge, which after installation of the glazing in the vehicle, runs along the roof liner, whereas the edge opposite the roof edge is referred to as the “engine edge”. The lateral edges of the windshield are, in the installed state, adjacent the vehicle body sections referred to as “A-pillars”. In this embodiment, the isolating line divides the electrically conductive coating into a first subregion between one lateral edge (adjacent one A-pillar) and the isolating line and a second subregion between the other lateral edge (adjacent the other A-pillar) and the isolating line. Such a division of the subregions is used, for example, to produce two switchable heating fields independent of one another. Another example would be a serial connection of these two heating fields, wherein a busbar electrically conductively connects the subregions across the isolating line. The method according to the invention has proved to be very effective for processing such substrates having an isolating line along the center of the pane perpendicular to the roof edge of the windshield.

Preferably, the substrate is the inner pane of the windshield. The substrate has an inner side on which the electrically conductive coating is situated and an outer side, which is directed toward the vehicle interior in the installed position. The second substrate is used as the outer pane of the windshield, wherein the inner side of the second substrate faces the substrate and the outer side of second substrate is oriented in the direction of the external environment of the vehicle. The thermoplastic intermediate layer, which bonds the substrates to one another, is situated between the inner pane and the inner side of the outer pane.

The invention further relates to the use of the method according to the invention for repairing isolating lines in conductive coatings in automobile glazing, preferably windshields, side windows, or rear windows, particularly preferably windshields.

The invention is described in detail in the following with reference to drawings and exemplary embodiments. The drawings are purely schematic representations and not true to scale. The drawings in no way restrict the invention.

They depict:

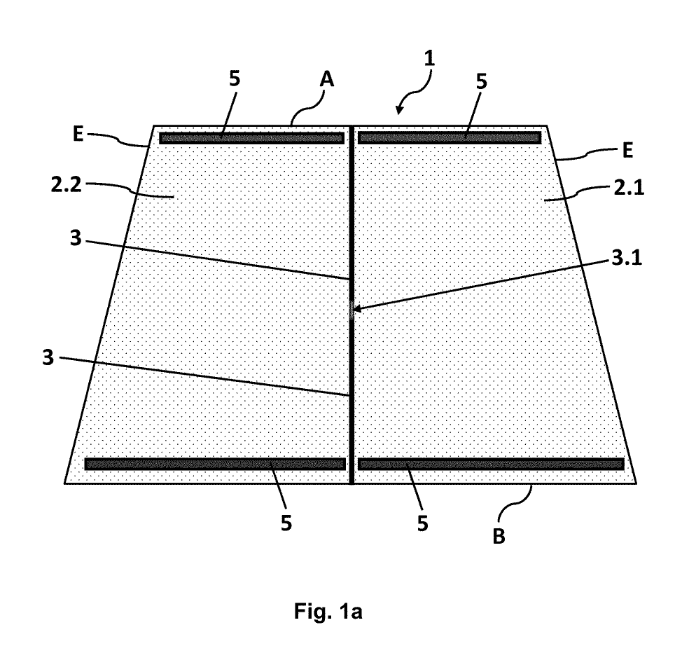

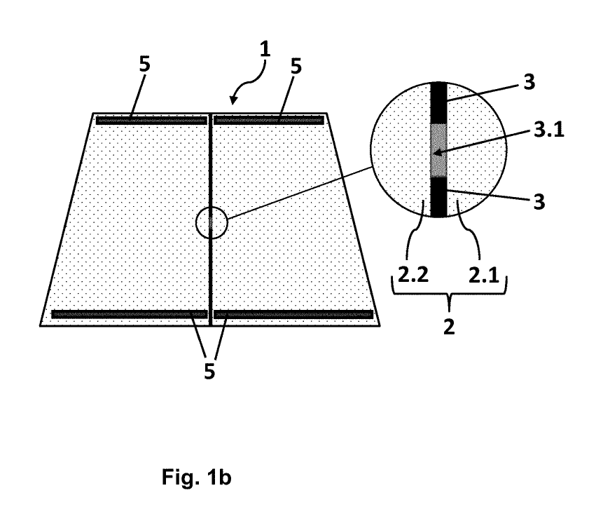

FIGS. 1a and 1b a substrate having an electrically conductive coating, which is divided by an isolating line into two subregions, wherein the isolating line has a defect,

FIG. 2 the substrate of FIGS. 1a and 1b, wherein in each case a contact is placed on the first subregion and on the second subregion, between which a current flows,

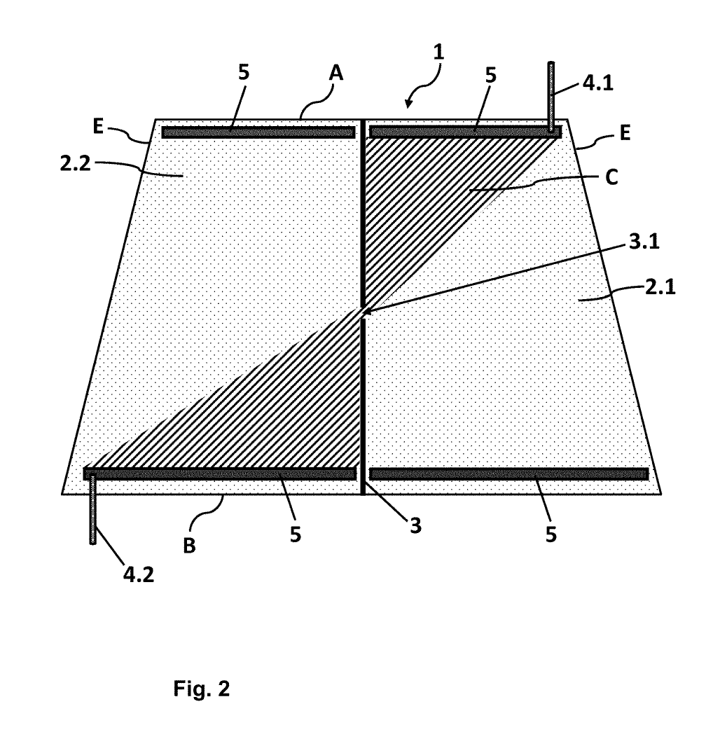

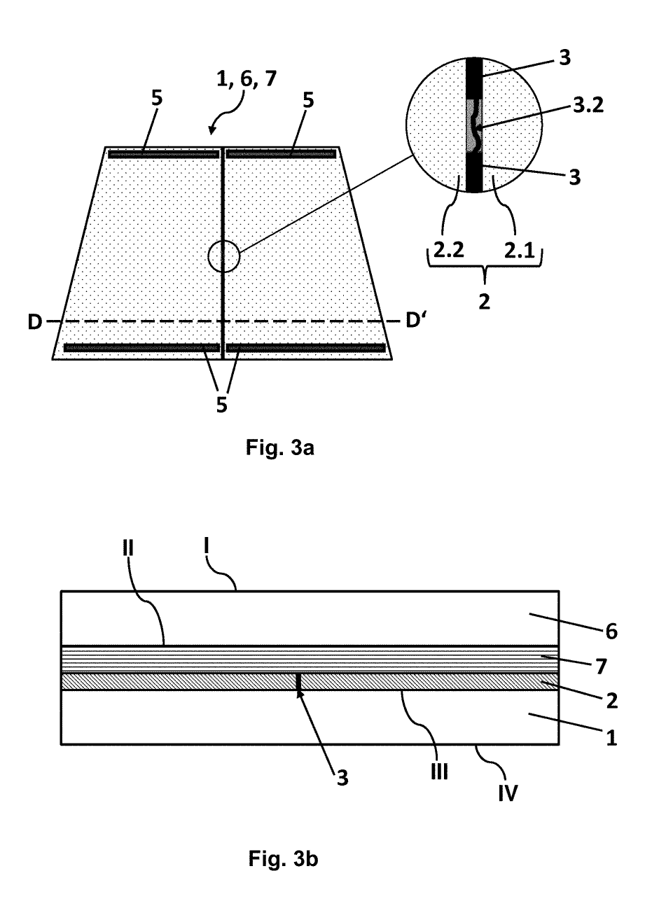

FIGS. 3a and 3b the substrate of FIGS. 1a and 1 b after execution of the method according to the invention, laminated as a composite pane with a second substrate and a thermoplastic intermediate layer,

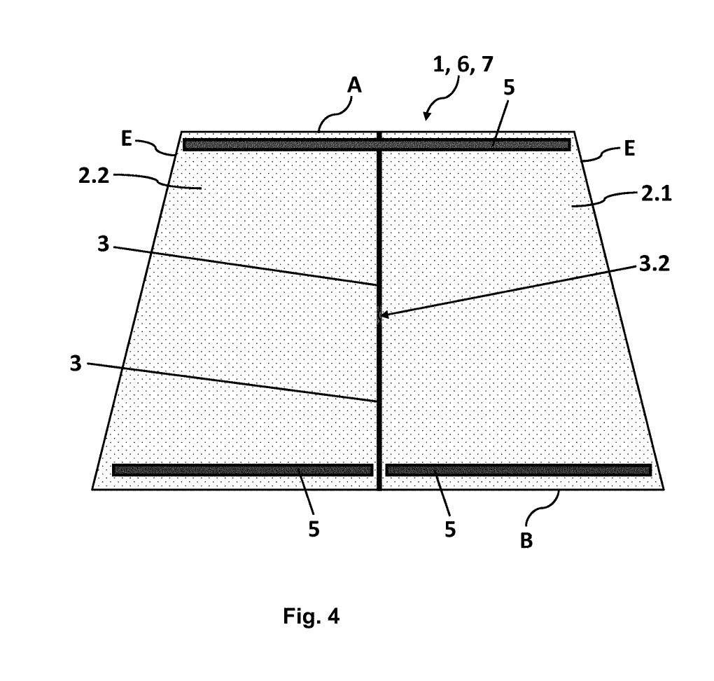

FIG. 4 another substrate after use of the method according to the invention, laminated as a composite pane with a second substrate and a thermoplastic intermediate layer,

FIG. 5 a detail of another substrate after use of the method according to the invention,

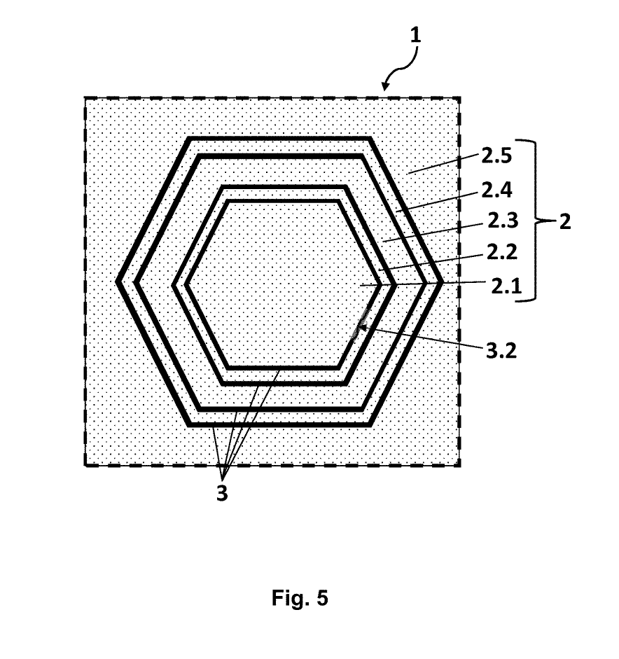

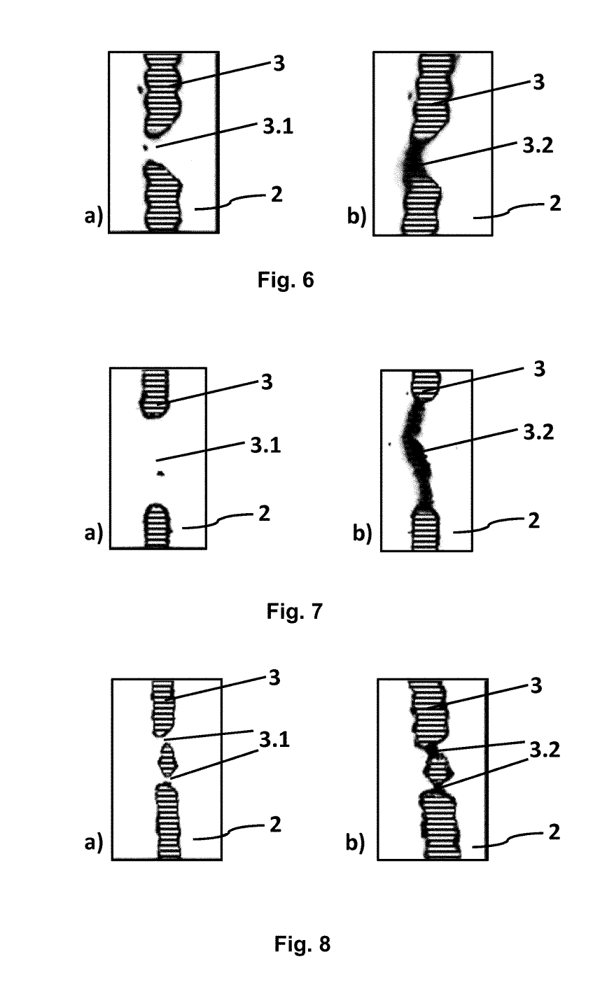

FIGS. 6, 7, and 8 a schematic enlarged representation in each case of a substrate before use of the method according to the invention (a) and after use of the method according to the invention (b),

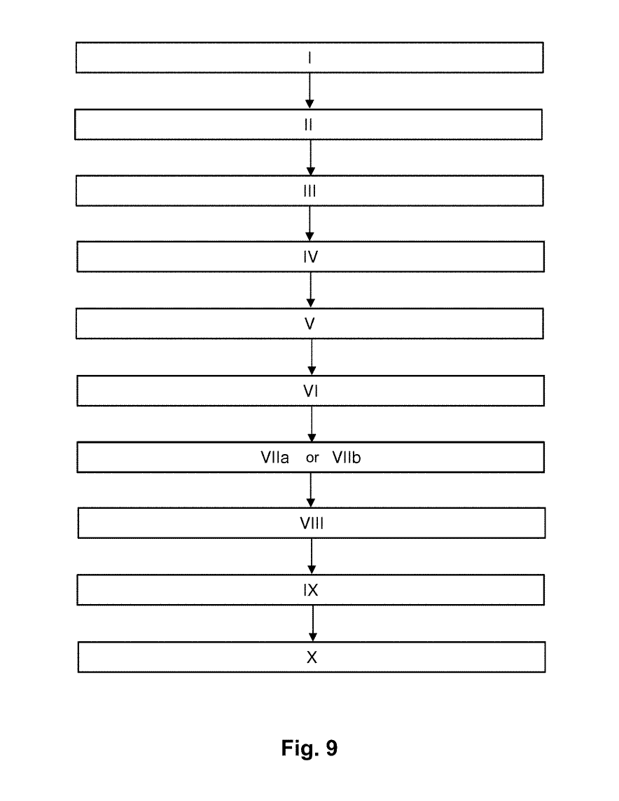

FIG. 9 a flowchart of an embodiment of the method according to the invention.

FIGS. 1a and 1b depict a substrate (1) having an electrically conductive coating (2), which is divided by an isolating line (3) with a width of 100 μm into a first subregion (2.1) and a second subregion (2.2), wherein the isolating line (3) has a defect (3.1). The isolating line (3) runs perpendicular to the roof edge (A) or to the engine edge (B). The basic shape of the substrate (1) corresponds to a windshield of a passenger car. Two busbars (5) in each case are applied in each of the subregions (2.1, 2.2). In each case one busbar (5) per subregion (2.1, 2.2) runs parallel to the roof edge (A) of the substrate (1), whereas one busbar per subregion (2.1, 2.2) is applied parallel to the engine edge (B) of the substrate (1). The busbars (5) extended each case only within one of the subregions (2.1, 2.2). Two heating fields switchable independently of one another are supposed to be produced by means of this arrangement of the busbars (5) and the isolating line (3). The substrate in FIGS. 1a and 1b is, however, not capable of functioning in this form since the isolating line (3) has a defect (3.1). FIG. 1b depicts an enlarged representation of the defect (3.1) of the isolating line (3). In the region of the defect (3.1), the first subregion (2.1) and the second subregion (2.2) of the coating (2) are electrically conductingly connected to one another. The defect (3.1) is caused by electrically conductive particles that establish an electrically conducting connection of the subregions (2.1, 2.2). The substrate (1) is made of soda lime glass with a thickness of 1.6 mm. The electrically conductive coating (2) includes three conductive silver layers with dielectric layers arranged therebetween. The electrically conductive coating (2) was deposited on the substrate (1) by magnetron sputtering. The isolating line (3) was introduced into the electrically conductive coating (2) by laser ablation. The busbars (5) are implemented as a printed conductive structure. For this, a silver-containing screenprinting paste was printed and fired. Since the subregions (2.1, 2.2) are electrically conductingly connected via the defect (3.1), independent heating of the subregions (2.1, 2.2) is not possible since a flow of current occurs via the defect (3.1). The substrate (1) is thus not commercially exploitable without remedying the defect (3.1).

FIG. 2 depicts the substrate of FIGS. 1a and 1 b, wherein in each case on one busbar (5) of each subregion (2.1, 2.2), an electric contact (4.1, 4.2) is electrically conductingly contacted. In the first subregion (2.1), the first electric contact (4.1) is placed on the busbar (5) situated adjacent the roof edge (A). Within this busbar (5), the first electric contact is positioned on the end of the busbar (5) adjacent the nearest side edge (E). The second electric contact (4.2) is mounted diagonally opposite the first electric contact (4.1) on a busbar (5) of the second subregion (2.2). The second electric contact (4.2) is placed in the second subregion (2.2) on the busbar (5) adjacent the engine edge (B). In this case, as well, the positioning is done on the end of the busbar (5) adjacent the nearest side edge (E). Upon application of a voltage between the electric contacts (4.1, 4.2), a current flows via the relevant busbar (5) and the coating (2) between the first electric contact (4.1) and the second electric contact (4.2). The flow of current between the subregions (2.1, 2.2) occurs exclusively via the defect (3.1), since this is the only electrically conducting connection of the subregions (2.1, 2.2). The defect (3.1) is thus the region of the substrate (1) with the highest current density. The region (C) through which the current flows is sketched in FIG. 2 as a hatched area. The performance of the method according to the invention is also possible with any positioning of the electric contacts (4.1, 4.2), as long as the two contacts (4.1, 4.2) are contacted in the different subregions (2.1, 2.2) such that upon application of a voltage, the flow of current occurs via the defect (3.1). A positioning according to FIG. 2 is advantageous if, in the previous production process, there is already a measurement station for resistance measurement and quality control that has correspondingly positioned contacts.

FIGS. 3a and 3b depict the substrate (1) of FIGS. 1a and 1b after execution of the method according to the invention laminated as a composite pane with a second substrate (6) and a thermoplastic intermediate layer (7). First, a first electric contact (4.1) and a second electric contact (4.2) were placed on the substrate (1) of FIGS. 1a and 1 b, wherein the arrangement corresponds to that depicted in FIG. 2. A voltage of 14 V was applied for 5 seconds between the first electric contact (4.1) and the second electric contact (4.2). The high current density in the region of the defect (3.1) results in very strong local heating in this region, by means of which a region with thermally decomposed coating is created, which runs between the ends of the isolating line (3) and thus completes the isolating line (3). In the region of the thus produced repaired defect (3.2), current no longer flows between the subregions (2.1, 2.2). The repaired defect (3.2) is recognizable as such with corresponding optical enlargement; however, is not discernible and is optically inconspicuous for the observer in everyday use of the pane. With regard to the heating behavior, the substrate (1) with a repaired defect (3.2) is indistinguishable from substrates whose isolating line never had a defect. The substrate (1) treated according to the method according to the invention is laminated according to FIGS. 3a and 3b via a thermoplastic intermediate layer (7) with a second substrate (6) to form a windshield, with FIG. 3a depicting a plan view and FIG. 3b depicts a cross-section of this arrangement along the section line D-D′. The substrate (1) with a repaired defect (3.2) of the isolating line (3) is, in this case, the inner pane of the windshield, wherein, in the installed position of the windshield, the outer side (IV) of the substrate (1) is directed toward the vehicle interior and the electrically conductive coating (2) is applied on the inner side (III) of the substrate (1). The thermoplastic intermediate layer (7) lies on the electrically conductive coating (2). The thermoplastic intermediate layer (7) is made of a polyvinyl butyral film with a thickness of 0.76 mm. The inner side (II) of the second substrate (6) is situated on the opposite surface of the thermoplastic intermediate layer (7). The second substrate (6) is made of soda lime glass with a thickness of 2.1 mm. The second substrate (6) is the outer pane of the windshield, with the outer side (I) of the second substrate (6) pointing in the direction of the external environment in the installed position.

FIG. 4 depicts another substrate (1) after use of the method according to the invention, mounting of busbars (5), and lamination with a thermoplastic intermediate layer (7) and a second substrate (6). The structure as well as the process parameters used correspond substantially to those described in FIGS. 3a and 3b. In contrast thereto, a single busbar (5), which electrically conductingly connects the first subregion (2.1) and the second subregion (2.2) is situated adjacent the roof edge (A). Such a configuration of the busbars (5) and the isolating line is, for example, selected in the case of windshields that are to be operated with a voltage of 42 V or 48 V. In particular, electric vehicles have these high on-board voltages, compared to the customary on-board voltage of 14 V. A pane design according to FIGS. 3a and 3b is designed for such an on-board voltage of 14 V, whereas higher voltages would result in undesirably high heating output. The configuration according to FIG. 4 results in that the two subregions (2.1, 2.2) function as serially connected heating fields, which results in a reduction of the heating output to the desired level. The method according to the invention is used in the case of a busbar configuration according to FIG. 4 prior to the mounting of the busbars (5). This is necessary since, otherwise, part of the flow of current occurs via the busbar (5) adjacent the roof edge (A) busbar (5) and not via the defect. After repair of the defect, the busbars (5) are applied and the substrate (1) is laminated analogously to the arrangement depicted in FIGS. 3a and 3b, yielding the composite pane according to FIG. 4.

FIG. 5 depicts a detail of another substrate (1) after use of the method according to the invention. The substrate (1) corresponds substantially to that described in FIGS. 1a and 1b. Various mutually concentric isolating lines (3) with a width of 35 μm are introduced into the coating, which lines divide the coating into subregions (2.1, 2.2, 2.3, 2.4, 2.5). The isolating line (3) running between the first subregion (2.1) and the second subregion (2.2) has a repaired defect (3.2). For repairing the defect, the method according to the invention was used, wherein the first electric contact was positioned at an arbitrary position within the first subregion (2.1) and the second electric contact was positioned at an arbitrary position within the second subregion (2.2), and a voltage of 10 V was applied for 3 seconds.

FIGS. 6, 7, and 8 depict, in each case, a schematic enlarged representation of a substrate (1) prior to use of the method according to the invention (a) and after use of the method according to the invention (b). The substrate (1) corresponded in all cases to that depicted in FIGS. 1a and 1 b. A voltage of 20 V was applied for 3 seconds between the electric contacts (4.1, 4.2) placed according to FIG. 2. A series of experiments was performed with 1000 substrates in which, prior to performance of the method according to the invention, 30% of the substrates had a defect (3.1) of the isolating line (3). After performance of the method according to the invention, the share of substrates having defects was successfully reduced to 0%. All defects (3.1) of the isolating line (3) were eliminated by using the method according to the invention. Some substrates (1) that previously had a defect (3.1) were randomly taken and examined before or after use of the method according to the invention. FIGS. 6, 7, and 8 depict an enlarged representation of the surroundings of the defect (3.1) before use of the method (see FIGS. 6a, 7a, and 8a) and after use of the method (see FIG. 6b, 7b, 8b). The isolating line (3) produced by laser ablation is represented as a hatched area in the coating (2). In this region, the coating (2) is removed. After use of the method according to the invention, the ends of the isolating line (3) adjacent the defect (3.1) are connected by a region with thermally decomposed coating within the coating (2). In the region of this thermally decomposed coating, conductive components are no longer present. Thus, flow of current no longer occurs via the resultant repaired defect (3.2).

FIG. 9 depicts a flowchart of an embodiment of the method according to the invention for producing the composite pane described in FIGS. 3a and 3b. The process steps depicted in FIG. 9 are as follows:
I Depositing an electrically conductive coating (2) on the inner side (III) of a substrate (1)
II Introducing the isolating line (3) in the electrically conductive coating (2) using laser ablation
III Applying the busbars (5) using screen printing
IV Contacting a first electric contact (4.1) with the first subregion (2.1) and contacting a second electric contact (4.2) with the second subregion (2.2) of the electrically conductive coating (2)
V Applying a voltage Uₙ between the first electric contact (4.1) and the second electric contact (4.2)
VI Measuring whether an electric current is flowing between the first subregion (2.1) and the second subregion (2.2)
VIIa If a current is flowing between the first subregion (2.1) and the second subregion (2.2): Repeating the steps V and VI with a voltage Uₙ₊₁, where Uₙ₊₁ is greater than Uₙ
VIIb If no current is flowing between the first subregion (2.1) and the second subregion (2.2): Continuing the method with step VIII
VIII Placing a thermoplastic intermediate layer (7) on the electrically conductive coating (2) of the substrate (1)
IX Placing a second substrate (6) on the thermoplastic intermediate layer (7), with the inner side (II) of the second substrate (6) facing in the direction of the thermoplastic intermediate layer (7)
X Laminating the layer stack to form a composite pane

The order of the steps II and III is arbitrary. Step III can, alternatively, also be done between step VIIb and step VIII.

### LIST OF REFERENCE CHARACTERS

(1) substrate
(2) electrically conductive coating
(2.1) first subregion of the electrically conductive coating
(2.2) second subregion of the electrically conductive coating
(2.n) n-th subregion of the electrically conductive coating, where n an integer >1
(3) isolating line
(3.1) defect of the isolating line
(3.2) repaired defect
(4) electric contacts
(4.1) first electric contact
(4.2) second electric contact
(5) busbar
(6) second substrate
(7) thermoplastic intermediate layer
(A) roof edge
(B) engine edge
(C) region through which current is flowing
D-D′ section line
(E) side edges
(I) outer side of the second substrate
(II) inner side of the second substrate
(III) inner side of the substrate
(IV) outer side of the substrate

1.-14. (canceled)

15. A method for processing a substrate having an electrically conductive coating and at least one isolating line, the method comprising:
a) providing a substrate, the substrate comprising:
a1) an electrically conductive coating on at least one surface of the substrate;
a2) at least one isolating line in the electrically conductive coating;
a3) at least one first subregion and one second subregion of the electrically conductive coating between which the isolating line runs;
a4) optionally, at least one defect of the isolating line in a region of the isolating line where a local sheet resistance is lower than a sheet resistance of the isolating line outside the defect;
b) electrically conductingly connecting a first electric contact to the first subregion and a second electric contact to the second subregion of the electrically conductive coating;
c) applying a voltage Uₙ between the first electric contact and the second electric contact;
d) measuring, using the first electric contact and the second electric contact, a flow of an electric current between the first subregion and the second subregion;
e) if an electric current is flowing between the first subregion and the second subregion, then repeating steps c) and d) with a voltage greater than or equal to Uₙ, until, in step d), a current flow can no longer be measured between the first subregion and the second subregion,
wherein an areal proportion of the defect to a total surface area of the isolating line is less than 10%.

16. The method according to claim 15, wherein the voltage greater than or equal to Uₙ of step e), is a voltage Uₙ₊₁, with Uₙ₊₁>Uₙ, that is increased iteratively with each repetition of the step e).

17. The method according to claim 15, wherein each of the voltages Uₙ and Uₙ₊₁ is less than 200 V.

18. The method according to claim 15, wherein each of the voltages Uₙ and Uₙ₊₁ is between 3 V and 50 V.

19. The method according to claim 17, wherein the voltage in step c) is applied for 1 second to 10 seconds.

20. The method according to claim 17, wherein the voltage in step c) is applied for 2 seconds to 6 seconds.

21. The method according to claim 15, wherein the first electric contact and the second electric contact directly contact the electrically conductive coating in the first subregion and the second subregion respectively.

22. The method according to claim 15, wherein:
prior to step b), at least one busbar is electrically conductingly applied on the electrically conductive coating in at least one of the first subregion and the second subregion, and
the at least one busbar produce no electric contact between the first subregion and the second subregion.

23. The method according to claim 22, wherein step b) further comprises contacting the first electric contact and the second electric contact to the at least one busbar.

24. The method according to claim 15, wherein after step e), the substrate is laminated, with interposition of a thermoplastic intermediate layer, to at least one second substrate to form a composite pane.

25. A substrate comprising an electrically conductive coating and at least one isolating line, wherein the at least one isolating line comprises at least one repaired defect obtained according to the method of claim 15.

26. The substrate according to claim 25, wherein the substrate comprises glass or plastics.

27. The substrate according to claim 26, wherein the glass comprises one or more of borosilicate glass and soda lime glass.

28. The substrate according to claim 26, wherein the plastics comprises one or more of polycarbonate, polymethylmethacrylate, polyethylene, and polyethylene terephthalate.

29. The substrate according to claim 25, wherein the electrically conductive coating contains at least one of: a) silver, and b) an electrically conductive oxide.

30. The substrate according to claim 25, wherein the substrate is laminated to a second substrate with interposition of a thermoplastic intermediate layer, to form a composite pane.

31. The substrate according to claim 30, wherein the substrate is laminated to form a windshield and the at least one isolating line runs along a center of the composite pane perpendicular to a roof edge of the windshield.

32. A method, comprising:
processing a substrate having an electrically conductive coating and at least one isolating line according to the method of claim 15; and
based on the processing, repairing the at least one isolating line in the electrically conductive coating,
wherein the substrate with the electrically conductive coating is used in automobile glazing.

33. The method according to claim 32, wherein the automobile glazing comprises at least one of: a) a windshield, b) a side window, and c) a rear window.
